(19) United States
(12) Patent Application Publication
(10) Pub. No.: US 2015/0382447 A1
(43) Pub. Date: Dec. 31, 2015

(54) MODULE ASSEMBLY AND DISPLAY DEVICE

(71) Applicant: SHENZHEN CHINA STAR OPTOELECTRONICS TECHNOLOGY CO., LTD., Shenzhen, Guangdong (CN)

(72) Inventors: Yu-Chun HSIAO, Shenzhen, Guangdong (CN); Gang YU, Shenzhen, Guangdong (CN); Dehua LI, Shenzhen, Guangdong (CN)

(21) Appl. No.: 14/387,682

(22) PCT Filed: Jul. 7, 2014
(86) PCT No.: PCT/CN2014/081775

§ 371 Date: Sep. 24, 2014

(30) Foreign Application Priority Data
Jun. 28, 2014 (CN) 201410306371.2

(51) Int. Cl. H05K 1/02; H05K 5/00

(52) U.S. Cl. CPC H05K 1/0212; H05K 5/0017; H05K 1/028; H05K 2201/068

(57) ABSTRACT

A module assembly is provided. The module assembly includes a back bezel, a heating member, and a thermal expansion member. The heating member is fixed on a first surface of the back bezel. The thermal expansion member is fixed on the heating member. The thermal expansion member has a first thermal expansion coefficient. The heating member is used to provide heat for the thermal expansion member. The thermal expansion member undergoes a first deformation based on the heat, so that the back bezel undergoes a second deformation. A display panel has a desired curved surface displaying effect on actual demands.

### FIELD OF THE INVENTION

The present invention relates to the technical field of displays, and in particular to a module assembly and a display device.

### BACKGROUND OF THE INVENTION

Commonly, the conventional display panels implement a curved surface displaying by the following two solutions.

The first solution is forcedly bending the back bezel to have a target curved surface with brackets.

Another solution is molding the back bezel directly to have the target curved surface.

In practice, the inventors have found that the prior arts have at least following problems:

The above two technical solutions merely provides that the back bezel is formed ahead with a fixed target curved surface but the back bezel (as display panel) cannot be variably formed with the target curved surface based on actual needs.

Therefore, it is necessary to propose a new technical solution to solve these technical problems.

### SUMMARY OF THE INVENTION

A primary object of the present invention is to provide a module assembly and a display device capable of facilitating formation of a display panel with a desired curved surface displaying effect on actual demands.

To achieve the above object, the technical solutions of the present invention are as follows.

A module assembly comprises a back bezel, a heating member fixed on a first surface of the back bezel, and a thermal expansion member which is fixed on the heating member and has a first thermal expansion coefficient. The heating member is used to provide heat for the thermal expansion member. The thermal expansion member undergoes a first deformation based on the heat provided by the heating member and applies a first active force to the back bezel, so that the back bezel undergoes a second deformation. The first heating member and the second heating member include a heating wire or a heating block. The back bezel includes a first board which has a second thermal expansion coefficient, and the second thermal expansion coefficient is less than the first thermal expansion coefficient.

In the module assembly described above, the back bezel includes a second board and a third board, the second board has a third thermal expansion coefficient, and the third board has a fourth thermal expansion coefficient. The third thermal expansion coefficient and the fourth thermal expansion coefficient are both less than the first thermal expansion coefficient.

In the module assembly described above, the second board and the third board are stacked and combined in integral, or the second board and the third board are spliced in integral.

In the module assembly described above, a predetermined distance is formed between the thermal expansion member and the first surface.

In the module assembly described above, after receiving the heat generated by the heating member, the first thermal expansion member and the second thermal expansion member are used to expand along a first direction to undergo the first deformation, and force the back bezel to undergo the second deformation. The first direction is a longitudinal direction of the first thermal expansion member and the second thermal expansion member and is parallel to long sides of a display panel.

In the module assembly described above, after receiving the heat generated by the heating member, the first thermal expansion member and the second thermal expansion member are used to expand along a second direction to undergo the first deformation, and force the back bezel to undergo the second deformation. The second direction is a longitudinal direction of the first thermal expansion member and the second thermal expansion member and is parallel to short sides of a display panel.

A module assembly comprises a back bezel, a heating member fixed on a first surface of the back bezel, and a thermal expansion member which is fixed on the heating member and has a first thermal expansion coefficient. The heating member is used to provide heat for the thermal expansion member. The thermal expansion member undergoes a first deformation based on the heat provided by the heating member and applies a first active force to the back bezel, so that the back bezel undergoes a second deformation.

In the module assembly described above, the back bezel includes a first board which has a second thermal expansion coefficient, and the second thermal expansion coefficient is less than the first thermal expansion coefficient.

In the module assembly described above, the back bezel includes a second board and a third board, the second board has a third thermal expansion coefficient, and the third board has a fourth thermal expansion coefficient.

The third thermal expansion coefficient and the fourth thermal expansion coefficient are both less than the first thermal expansion coefficient.

In the module assembly described above, the second board and the third board are stacked and combined in integral, or the second board and the third board are spliced in integral.

In the module assembly described above, a predetermined distance is formed between the thermal expansion member and the first surface.

In the module assembly described above, after receiving the heat generated by the heating member, the first thermal expansion member and the second thermal expansion member are used to expand along a first direction to undergo the first deformation, and force the back bezel to undergo the second deformation. The first direction is a longitudinal direction of the first thermal expansion member and the second thermal expansion member and is parallel to long sides of a display panel.

In the module assembly described above, after receiving the heat generated by the heating member, the first thermal expansion member and the second thermal expansion member are used to expand along a second direction to undergo the first deformation, and force the back bezel to undergo the second deformation. The second direction is a longitudinal direction of the first thermal expansion member and the second thermal expansion member and is parallel to short sides of a display panel.

A display device comprises a display panel and a module assembly which is assembled with the display panel in integral. The module assembly comprises a back bezel, a heating member fixed on a first surface of the back bezel; and a thermal expansion member fixed on the heating member and having a first thermal expansion coefficient. The heating member is used to provide heat for the thermal expansion member. The thermal expansion member undergoes a first deformation based on the heat provided by the heating member and applies a first active force to the back bezel, so that the back bezel undergoes a second deformation. When the back bezel undergoes the second deformation, the module assembly is used to apply a second force to the display panel, so that the display panel undergoes a third deformation.

In the module assembly described above, the back bezel includes a first board having a second thermal expansion coefficient, and the second thermal expansion coefficient is less than the first thermal expansion coefficient.

In the module assembly described above, the back bezel includes a second board and a third board, the second board has a third thermal expansion coefficient, and the third board has a fourth thermal expansion coefficient. The third thermal expansion coefficient and the fourth thermal expansion coefficient are both less than the first thermal expansion coefficient.

In the module assembly described above, the second board and the third board are stacked and combined in integral, or the second board and the third board are spliced in integral.

In the module assembly described above, a predetermined distance is formed between the thermal expansion member and the first surface.

In the module assembly described above, after receiving the heat generated by the heating member, the first thermal expansion member and the second thermal expansion member are used to expand along a first direction to undergo the first deformation, and force the back bezel to undergo the second deformation. The first direction is a longitudinal direction of the first thermal expansion member and the second thermal expansion member and is parallel to long sides of a display panel.

In the module assembly described above, after receiving the heat generated by the heating member, the first thermal expansion member and the second thermal expansion member are used to expand along a second direction to undergo the first deformation, and force the back bezel to undergo the second deformation. The second direction is a longitudinal direction of the first thermal expansion member and the second thermal expansion member and is parallel to short sides of a display panel.

Relative to the prior arts, the present invention allows the display panel to be curved based on actual needs, so as to have the desired curved surface displaying effect.

In order to make the forgoing content of the present invention easily understood, preferred embodiments and a detailed description are provided below in junction with the accompanying drawings.

### BRIEF DESCRIPTION OF THE DRAWINGS

FIG. 1 is an isometric view of a display device in accordance with a first embodiment of the present invention;

FIG. 2 is an exploded view of the display device shown in FIG. 1;

FIG. 3 is an isometric view of the display device shown in FIG. 1, which undergoes a deformation state;

FIG. 4 is an exploded view of the display device shown in FIG. 1, which undergoes a deformation state;

FIG. 5 is an isometric view of a display device in accordance with a second embodiment of the present invention;

FIG. 6 is an exploded view of the display device as shown in FIG. 5;

FIG. 7 is an isometric view of the display device shown in FIG. 5, which undergoes a deformation state; and

FIG. 8 is an exploded view of the display device shown in FIG. 5, which undergoes a deformation state.

### DETAILED DESCRIPTION OF THE PREFERRED EMBODIMENTS

The following descriptions of the embodiments by reference to the accompanying drawings illustrate particular embodiments of the present invention which can be implemented.

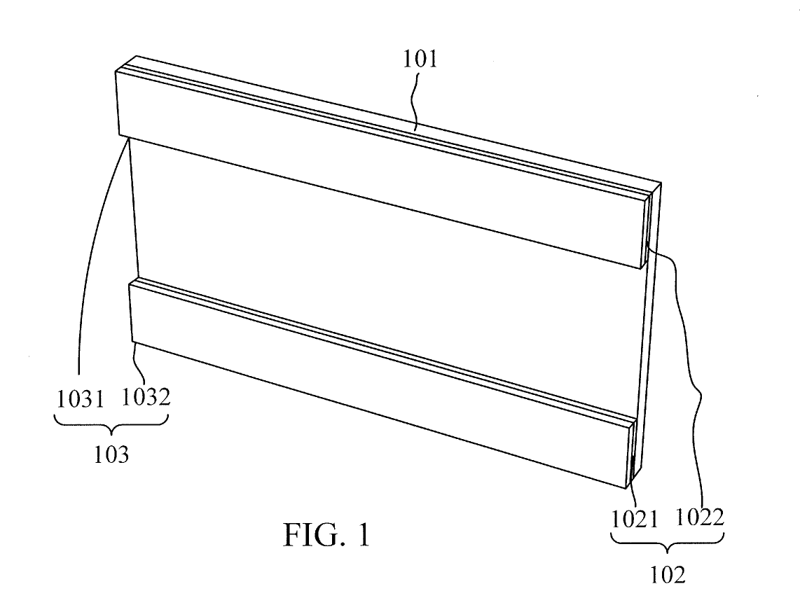

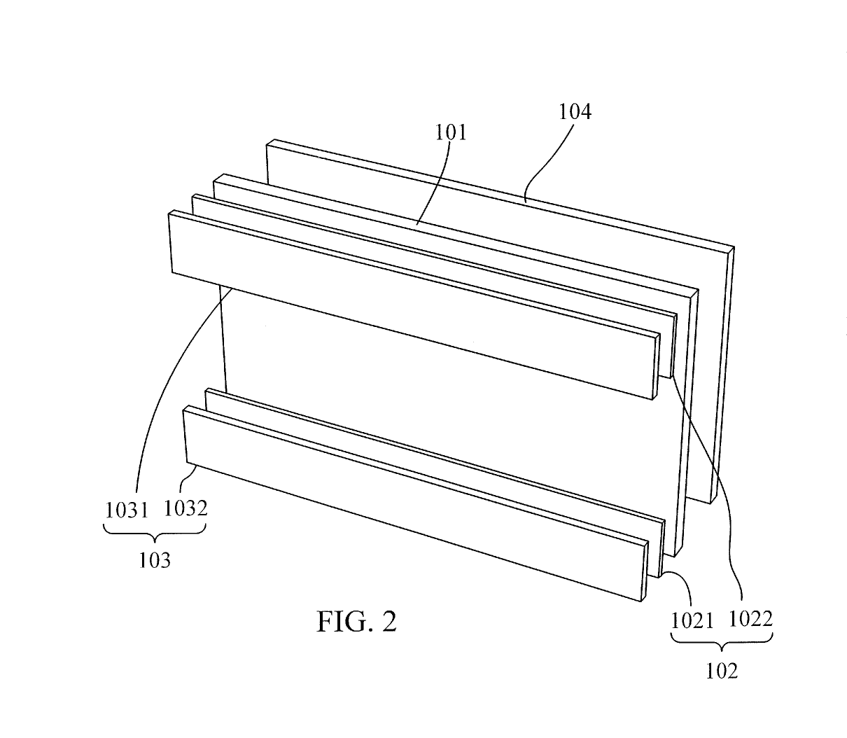

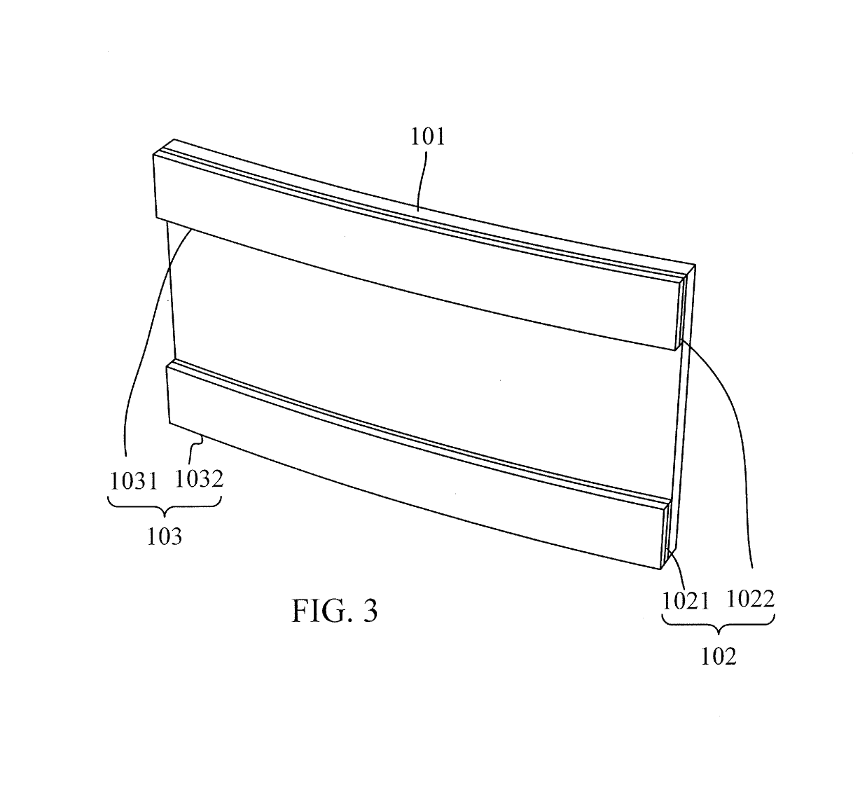

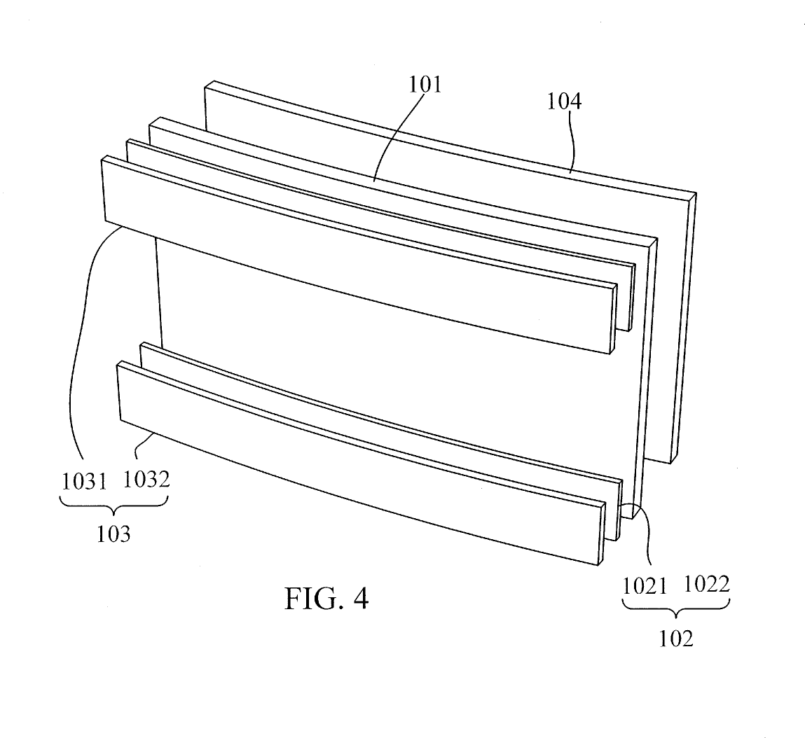

Referring to FIGS. 1-4, FIG. 1 is an isometric view of the display device in accordance with a first embodiment of the present invention, FIG. 2 is an exploded view of the display device as shown in FIG. 1, FIG. 3 is an isometric view of the display device, which undergoes the deformation state as shown in FIG. 1, and FIG. 4 is an exploded view of the display device, which undergoes the deformation state as shown in FIG. 1.

The display device of the embodiment includes a display panel 104 and the module assembly. The module assembly and the display panel 104 are assembled in integral. The module assembly includes a back bezel 101, a heating member 102 and a thermal expansion member 103.

The heating member 102 is fixed on a first surface of the back bezel 101. The first surface is an outer surface of the back bezel 101. In other words, the first surface is a surface facing away from the display panel 104, and a second surface (an inner surface) of the back bezel 101 faces toward the display panel 104.

The heating member 102 covers a part or all of the first surface. In the present embodiment, the heating member 102 covering a part of the first surface is illustrated.

In the present embodiment, the heating member 102 comprises a first heating member 1021 and a second heating member 1022. The first heating member 1021 and the second heating member 1022 are disposed in parallel to each other. A line where the first heating member 1021 is located is parallel to a first direction which is parallel to a long side of the display panel 104.

In the present embodiment, there is a predetermined distance S formed between the thermal expansion member 103 and the first surface. Specifically, the heating member 102 is a plate shape having a thickness corresponding to the predetermined distance S. The first heating member 1021 and the second heating member 1022 include a heating wire, heating block or other components.

The thermal expansion member 103 is fixed on the heating member 102. The thermal expansion member 103 can be fixed on the heating member 102 by bonding or welding. The thermal expansion member 103 can also be fixed on the heating member 102 via screws. Specifically, the thermal expansion member 103 comprises a first thermal expansion member 1031 and a second thermal expansion 1032. The first thermal expansion member 1031 is fixed on the first heating member 1021, and the second thermal expansion member 1032 is fixed on the second heating member 1022.

The thermal expansion member 103 has a first thermal expansion coefficient. The heating member 102 is used to provide heat for the thermal expansion member 103, the thermal expansion member 103 undergoes a first deformation based on the heat provided by the heating member 103 and applies a first active force to the back bezel 101 so that the back bezel undergoes a second deformation. The first active force is obtained by the thermal expansion member 103 converting the heat provided by the heating member 102.

Specifically, after receiving the heat generated by the heating member 102, the first thermal expansion member 1031 expands along a first direction (as a longitudinal direction of the first thermal expansion member 1031) to undergo the first deformation, and forces the back bezel 101 to bend (as undergoing the second deformation). After receiving the heat generated by the heating member 102, the second thermal expansion member expands along a first direction (the longitudinal direction of the second thermal expansion member 1032) to undergo the first deformation, and forces the back bezel 101 to bend (as undergoing the second deformation).

When the back bezel 101 undergoes the second deformation, the module assembly is used to apply a second active force to the display panel 104 so that the display panel 104 undergoes a third deformation. Preferably, in this embodiment, the display panel 104 is a flexible panel. In other words, the display panel 104 is a bendable panel under undergoing a force. The third deformation and the second deformation correspond to a bend along a third direction. The third direction is directed from the first surface of the back bezel 101 to the second surface.

In the present embodiment, the back bezel 101 comprises a first board. In other words, the back bezel 101 is a single plate construed of a material corresponding to a single thermal expansion coefficient. The first board has a second thermal expansion coefficient which is less than the first thermal expansion coefficient so that a thermal expansion rate of the back bezel 101 is smaller than that of the thermal expansion member 103.

In the present embodiment, the display device may further include a temperature controller, which is connected with the heating member 102. The temperature controller is used to turn on or off the heating member 102, and to control the amount of heat generated by the temperature of the heating member 102.

Moreover, the display device may further include a temperature sensor for sensing (measuring) the temperature of the heating member or the thermal expansion member 103. The temperature sensor is also used to transmit the sensed (measured) temperature data to the temperature controller so that the temperature controller controls the heat generated by the heating member 102.

Furthermore, the temperature controller is further used to control the heat generated by the heating member 102 based on a user's instructions in operation.

After the heat provided by the heating member 102 is obtained, the expansion amount in the longitudinal direction of the thermal expansion member 103, depending on the temperature variances, is defined by the following equation:

ΔL=f (Δt), wherein ΔL is the expansion amount in the longitudinal direction of the thermal expansion member 103, and Δt is a temperature change amount.

If the temperature of the thermal expansion member 103 is raised by Δt from the room temperature, the length of the back bezel 101 is L1, and a length of the bracket is L2, then ΔL=L2−L1=f (Δt)=θ*ΔH. Therefore, θ=f (Δt)/ΔH. The radius of curvature of the back bezel 101 R1=L1/θ=L1*θ/f(Δt).

Thus, the temperature change amount Δt can be controlled by controlling the heat generated by the heating member 102, thereby controlling the curvature radius of the second deformation of the back bezel 101.

Through the above technical solution, the display panel 104 can be bent based on the actual needs (as undergoing deformation) so as to have a variety of desired curved surface displaying effects.

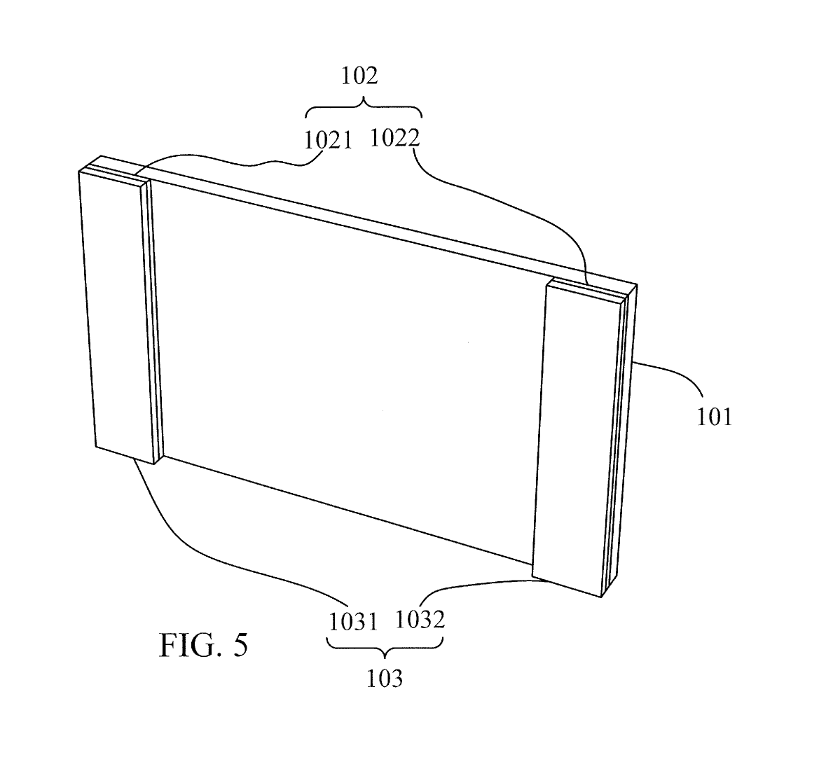

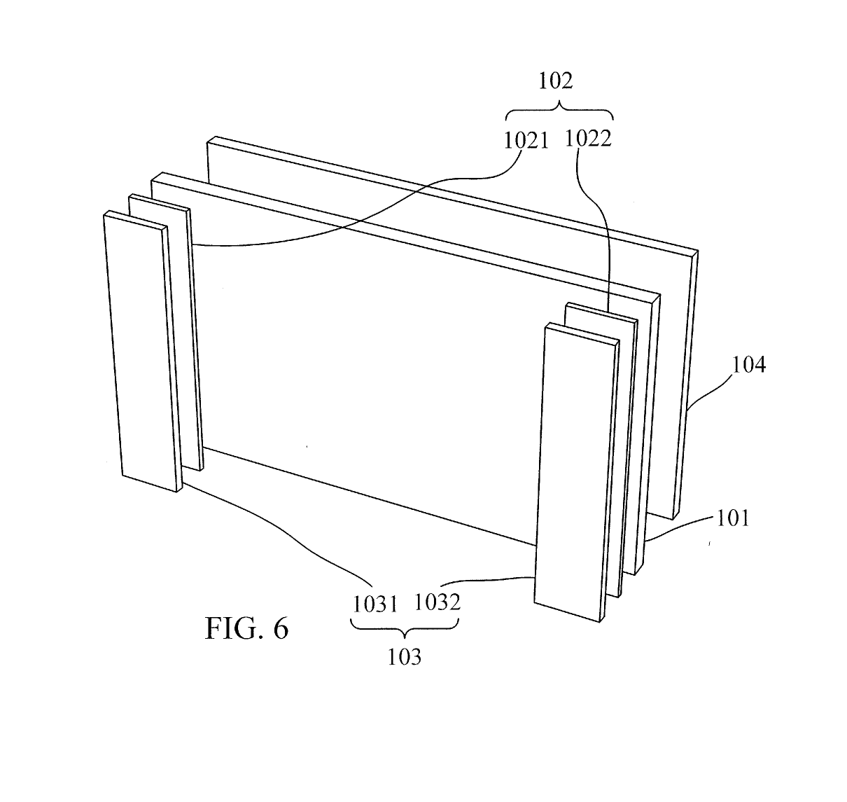

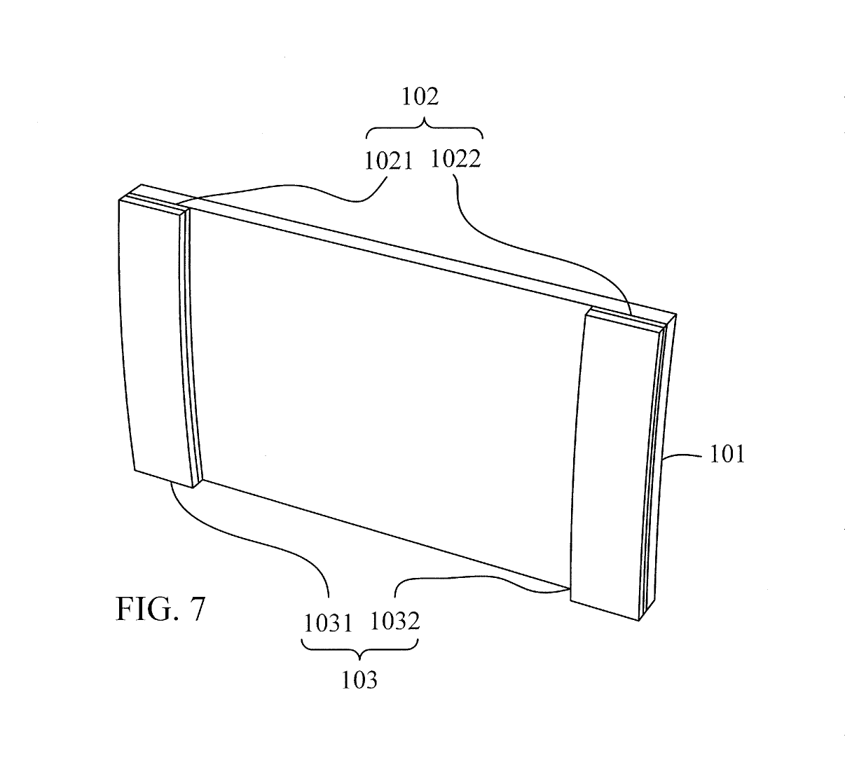

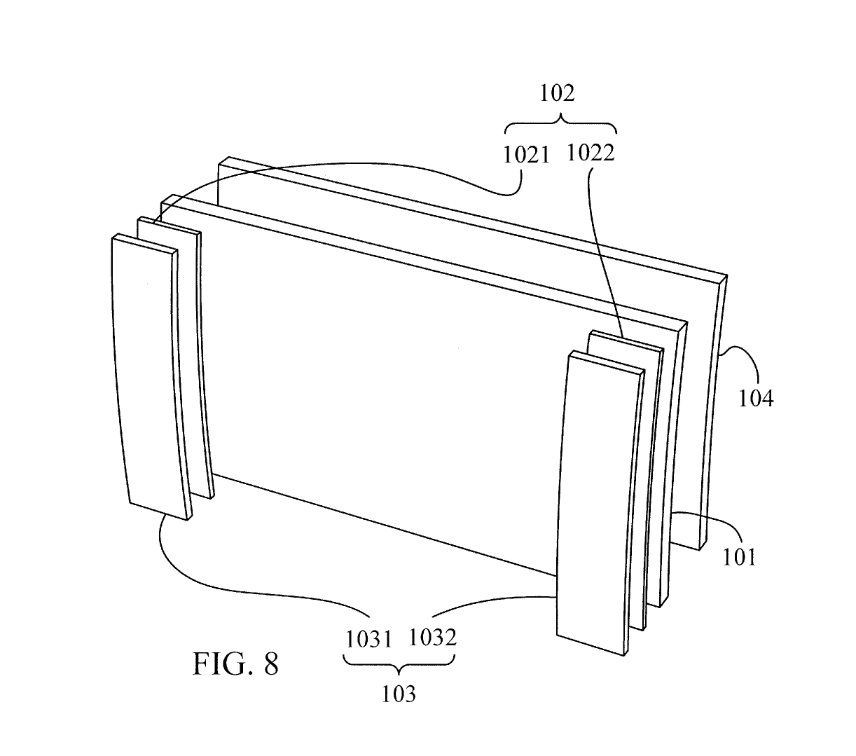

Referring to FIGS. 5-8, FIG. 5 is an isometric view of the display device in accordance with a second embodiment of the present invention, FIG. 6 is an exploded view of the display device as shown in FIG. 5, FIG. 7 is an isometric view of the display device, which undergoes the deformation state as shown in FIG. 5, and FIG. 8 is an exploded view of a display device, which undergoes the deformation state as shown in FIG. 5.

This embodiment is similar to the above-described first embodiment, except that:

In the present embodiment, the lines (the longitudinal direction) where the first heating member 1021 and the second heating member 1022 are located are parallel to a second direction which is parallel to a short side of the display panel 104.

After receiving the heat generated by the heating member 102, the first thermal expansion member 1031 expands along a second direction (as the longitudinal direction of the first thermal expansion member 1031) to undergo the first deformation, and forces the back bezel 101 to bend (as undergoing the second deformation). After receiving the heat generated by the heating member 102, the second thermal expansion member expands along a second direction (as the longitudinal direction of the second thermal expansion member 1032) to undergo the first deformation, and forces the back bezel 101 to bend (as undergoing the second deformation).

A third embodiment of a display device of the present invention is similar to the above-described first embodiment or the second embodiment, except that:

In the present embodiment, a back bezel 101 includes a second board and a third board both stacked in integral. The second board has a third thermal expansion coefficient, and the third board has a fourth thermal expansion coefficient. The third thermal expansion coefficient and the fourth thermal expansion coefficient are less than the first thermal expansion coefficient.

A fourth embodiment of the display device of the present invention is similar to the above-described third embodiment, except that:

The second board and the third board are spliced in integral. The first heating member 1021 is disposed on the second board, and the second heating member 1022 is disposed on the third board.

In summary, although the preferred embodiments of the present invention are disclosed above, the foregoing preferred embodiments are not intended to limit the present invention. One of ordinary skill in the art may make various modifications and variations without departing from the spirit and within scope of the present invention. Thus, the scopes of the invention are defined by the claims.

What is claimed is:

1. A module assembly, comprising:
a back bezel;
a heating member fixed on a first surface of the back bezel; and
a thermal expansion member fixed on the heating member and having a first thermal expansion coefficient,
wherein the heating member is used to provide heat for the thermal expansion member, the thermal expansion member undergoes a first deformation based on the heat provided by the heating member and applies a first active force to the back bezel so that the back bezel undergoes a second deformation;
the first heating member and the second heating member include a heating wire or a heating block;
the back bezel includes a first board having a second thermal expansion coefficient; and
the second thermal expansion coefficient is less than the first thermal expansion coefficient.

2. The module assembly as claimed in claim 1, wherein
the back bezel includes a second board and a third board,
the second board has a third thermal expansion coefficient, the third board has a fourth thermal expansion coefficient, and
the third thermal expansion coefficient and the fourth thermal expansion coefficient are both less than the first thermal expansion coefficient.

3. The module assembly as claimed in claim 2, wherein
the second board and the third board are stacked in integral or the second board and the third board are spliced in integral.

4. The module assembly as claimed in claim 1, wherein
a predetermined distance is formed between the thermal expansion member and the first surface.

5. The module assembly as claimed in claim 1, wherein
after receiving the heat generated by the heating member, the first thermal expansion member and the second thermal expansion member are used to expand along a first direction to undergo the first deformation, and force the back bezel to undergo the second deformation, wherein the first direction is a longitudinal direction of the first thermal expansion member and the second thermal expansion member and is parallel to a long side of a display panel.

6. The module assembly as claimed in claim 1, wherein
after receiving the heat generated by the heating member, the first thermal expansion member and the second thermal expansion member are used to expand along a second direction to undergo the first deformation, and force the back bezel to undergo the second deformation, wherein the second direction is a longitudinal direction of the first thermal expansion member and the second thermal expansion member and is parallel to a short side of a display panel.

7. A module assembly, comprising:
a back bezel;
a heating member fixed on a first surface of the back bezel; and
a thermal expansion member fixed on the heating member and having a first thermal expansion coefficient,
wherein the heating member is used to provide heat for the thermal expansion member, and the thermal expansion member undergoes a first deformation based on the heat provided by the heating member and applies a first active force to the back bezel so that the back bezel undergoes a second deformation.

8. The module assembly as claimed in claim 7, wherein
the back bezel includes a first board having a second thermal expansion coefficient, and
the second thermal expansion coefficient is less than the first thermal expansion coefficient.

9. The module assembly as claimed in claim 7, wherein
the back bezel includes a second board and a third board,
the second board has a third thermal expansion coefficient, the third board has a fourth thermal expansion coefficient, and
the third thermal expansion coefficient and the fourth thermal expansion coefficient are both less than the first thermal expansion coefficient.

10. The module assembly as claimed in claim 9, wherein
the second board and the third board are stacked in integral or
the second board and the third board are spliced in integral.

11. The module assembly as claimed in claim 7, wherein
a predetermined distance is formed between the thermal expansion member and the first surface.

12. The module assembly as claimed in claim 7, wherein
after receiving the heat generated by the heating member, the first thermal expansion member and the second thermal expansion member are used to expand along a first direction to undergo the first deformation, and force the back bezel to undergo the second deformation, wherein the first direction is a longitudinal direction of the first thermal expansion member and the second thermal expansion member and is parallel to a long side of a display panel.

13. The module assembly as claimed in claim 7, wherein
after receiving the heat generated by the heating member, the first thermal expansion member and the second thermal expansion member are used to expand along a second direction to undergo the first deformation, and force the back bezel to undergo the second deformation, wherein the second direction is a longitudinal direction of the first thermal expansion member and the second thermal expansion member and is parallel to a short side of a display panel.

14. A display device, comprising:
a display panel; and
a module assembly assembled in integral with the display panelin integral, and comprising:
a back bezel;
a heating member fixed on a first surface of the back bezel; and
a thermal expansion member fixed on the heating member and having a first thermal expansion coefficient,
wherein the heating member is used to provide heat for the thermal expansion member, the thermal expansion member undergoes a first deformation based on the heat provided by the heating member and applies a first active force to the back bezel so that the back bezel undergoes a second deformation, and wherein the back bezel undergoes the second deformation, the module assembly is used to apply a second active force to the display panel so that the display panel undergoes a third deformation.

15. The module assembly as claimed in claim 14, wherein
the back bezel includes a first board having a second thermal expansion coefficient, and the second thermal expansion coefficient is less than the first thermal expansion coefficient.

16. The module assembly as claimed in claim 14, wherein
the back bezel includes a second board and a third board,
the second board has a third thermal expansion coefficient, the third board has a fourth thermal expansion coefficient, and
the third thermal expansion coefficient and the fourth thermal expansion coefficient are both less than the first thermal expansion coefficient.

17. The module assembly as claimed in claim 16, wherein
the second board and the third board are stacked in integral or
the second board and the third board are spliced in integral.

18. The module assembly as claimed in claim 14, wherein
a predetermined distance is formed between the thermal expansion member and the first surface.

19. The module assembly as claimed in claim 14, wherein
after receiving the heat generated by the heating member, the first thermal expansion member and the second thermal expansion member are used to expand along a first direction to undergo the first deformation, and force the back bezel to undergo the second deformation, wherein the first direction is a longitudinal direction of the first thermal expansion member and the second thermal expansion member and is parallel to a long side of a display panel.

20. The module assembly as claimed in claim 14, wherein
after receiving the heat generated by the heating member, the first thermal expansion member and the second thermal expansion member are used to expand along a second direction to undergo the first deformation, and force the back bezel to undergo the second deformation, wherein the second direction is a longitudinal direction of the first thermal expansion member and the second thermal expansion member and is parallel to a short side of a display panel.
